(19) United States
(12) Patent Application Publication
(10) Pub. No.: US 2024/0357860 A1
(43) Pub. Date: Oct. 24, 2024

(54) DISPLAY PANEL, DISPLAY DEVICE INCLUDING THE SAME, AND MANUFACTURING METHOD THEREOF

(71) Applicant: Samsung Display Co., LTD., Yongin-si (KR)

(72) Inventors: Byung Han YOO, Yongin-si (KR); Chung Sock CHOI, Yongin-si (KR); Jung Woo PARK, Yongin-si (KR); Gun Hee KIM, Yongin-si (KR); Dae Young LEE, Yongin-si (KR)

(21) Appl. No.: 18/415,980

(22) Filed: Jan. 18, 2024

(30) Foreign Application Priority Data
Apr. 21, 2023 (KR) 10-2023-0052762

(51) Int. Cl. H10K 59/121; H10K 39/34; H10K 59/12

(52) U.S. Cl. CPC H10K 59/1213; H10K 39/34; H10K 59/1201

(57) ABSTRACT

A display panel includes: a base substrate; a thin film transistor layer on the base substrate and including: a lower metal layer configured to receive a low potential voltage; a pixel circuit including at least one transistor; and a sensor circuit electrically connected to the lower metal layer; and an element layer on the thin film transistor layer having a light emitting element including: a first pixel electrode electrically connected to the pixel circuit; a second pixel electrode configured to receive the low potential voltage; and a light receiving element electrically connected to the sensor circuit and configured to receive the low potential voltage from the lower metal layer.

### CROSS-REFERENCE TO RELATED APPLICATION

The present application claims priority to and the benefit of Korean Patent Application No. 10-2023-0052762, filed on Apr. 21, 2023, in the Korean Intellectual Property Office, the entire disclosure of which is incorporated herein by reference.

### BACKGROUND

### 1. Field

Aspects of some embodiments of the present disclosure relate to a display panel, a display device including the same, and a manufacturing method thereof.

### 2. Description of the Related Art

As information technology develops, electronic devices (for example, mobile devices) are evolving to provide various functions to users of electronic devices in addition to a function of displaying images through a display panel.

For example, a user's unique biometric information (for example, a fingerprint and the like) may be obtained through a photo sensor provided on a display panel, and a high-security biometric authentication function may be provided using the obtained biometric information.

The above information disclosed in this Background section is only for enhancement of understanding of the background and therefore the information discussed in this Background section does not necessarily constitute prior art.

### SUMMARY

Aspects of some embodiments of the present disclosure include a display panel with relatively improved sensing accuracy of a photo sensor, a display device including the same, and a manufacturing method thereof.

Aspects of some embodiments of the present disclosure include a display panel including: a base substrate; a thin film transistor layer that is located on the base substrate, in which a lower metal layer to which a low potential voltage is applied is located, that includes a pixel circuit including at least one transistor, and that includes a sensor circuit electrically connected to the lower metal layer; and an element layer that is located on the thin film transistor layer, that includes a light emitting element including a first pixel electrode electrically connected to the pixel circuit and a second pixel electrode to which the low potential voltage is applied, and that includes a light receiving element electrically connected to the sensor circuit and receiving the low potential voltage from the lower metal layer.

According to some embodiments, the element layer may further include a partition wall member surrounding the light receiving element.

According to some embodiments, the thin film transistor layer may include a multi-layered source-drain electrode layer; and a planarization insulating film exposing at least a portion of the source-drain electrode layer, and the lower metal film may be electrically connected to the source-drain electrode layer.

According to some embodiments, the second pixel electrode may include a conductive layer having light transmission. According to some embodiments, the light emitting element may include a first sensor electrode connected to the source-drain electrode layer and a second sensor electrode including the conductive layer. According to some embodiments, the second sensor electrode may be connected to a side surface of the exposed source-drain electrode layer.

According to some embodiments, the source-drain electrode layer may include first and third layers containing titanium and a second layer containing aluminum. According to some embodiments, the second sensor electrode may be connected to the second layer of the source-drain electrode layer.

According to some embodiments, the second layer may include an inclined side wall. According to some embodiments, the second sensor electrode may be connected to the inclined side wall of the second layer.

According to some embodiments, the second pixel electrode and the second sensor electrode may be disconnected from each other.

According to some embodiments, the thin film transistor layer may include: a buffer layer located on the base substrate; the lower metal layer located on the buffer layer; a first interlayer insulating layer covering the lower metal layer; a first active pattern located on the first interlayer insulating layer; a first gate insulating layer covering the first active pattern and arranged to overlap a channel region of the first active pattern; a first gate electrode layer arranged on the first gate insulating layer; a second interlayer insulating layer covering the first gate electrode layer; a second active pattern on the second interlayer insulating layer; a second gate insulating layer covering the second active pattern; a second gate electrode layer on the second gate insulating layer and arranged to overlap a channel region of the second active pattern; a third interlayer insulating layer covering the second gate electrode layer; and a first source-drain electrode layer located on the third interlayer insulating layer and connected to the lower metal layer, the first active pattern, and the second active pattern.

According to some embodiments, the first source-drain electrode layer may include: a first source electrode connected to a source region of the first active pattern; a first drain electrode connected to a drain area of the first active pattern; a second source electrode connected to the lower metal layer and a source region of the second active pattern; and a second drain electrode connected to a drain area of the second active pattern.

According to some embodiments, the thin film transistor layer may further include: a first planarization insulating layer covering the first source-drain electrode layer; a second source-drain electrode layer located on the first planarization insulating film and connected to the first source-drain electrode layer; and a second planarization insulating layer on the second source-drain electrode layer and exposing at least a portion of the second source-drain electrode layer.

According to some embodiments, the second source-drain electrode layer and the light receiving element may be connected in an area in which at least a portion of the second planarization insulating layer is removed so that at least a portion of the second source-drain electrode layer is exposed.

Aspects of some embodiments of present disclosure include a manufacturing method of a display panel including: forming a lower metal layer on a base substrate; forming a first active pattern on the lower metal layer; forming a first gate electrode layer overlapping a channel region of the first active pattern; forming a second active pattern on the first gate electrode layer; forming a second gate electrode layer overlapping a channel region of the second active pattern; forming a first source-drain electrode layer that includes a first source electrode connected to a source region of the first active pattern, a first drain electrode connected to a drain region of the first active pattern, a second source electrode connected to a source region of the second active pattern and the lower metal layer, and a second drain electrode connected to a drain region of the second active pattern; forming a second source-drain electrode layer including a connection electrode connected to the second drain electrode; forming a first pixel electrode of a light emitting element and a first sensor electrode of a light receiving element; forming an emission layer on the first pixel electrode; forming a light receiving layer on the first sensor electrode; and forming a light transmitting conductive layer that includes a second pixel electrode formed on the emission layer and a second sensor electrode of a light receiving element connected to the second source-drain electrode layer.

According to some embodiments, the forming of the first active pattern may include a low temperature polycrystalline silicon process. According to some embodiments, the forming of the second active pattern may include a metal oxide semiconductor process.

According to some embodiments, the manufacturing method of the display panel may further include forming a first planarization insulating layer covering the first source-drain electrode layer; forming a second source-drain electrode layer connected to the first source-drain electrode layer on the first planarization insulating layer; forming a second planarization insulating layer on the second source-drain electrode layer; forming a bank layer on the second planarization insulating layer; forming a partition wall member on the bank layer; and removing at least a portion of the second planarization insulating layer and at least a portion of the bank layer and exposing the second source-drain electrode layer.

According to some embodiments, the forming of the second source-drain electrode layer may include forming a first layer containing titanium; forming a second layer containing aluminum and having a narrower width than the first layer; and forming a third layer containing titanium and having a wider width than the second layer. According to some embodiments, the forming of the light transmitting conductive layer may include connecting a second sensor electrode of the light receiving element and a side wall of the second layer.

According to some embodiments, in the forming of the second layer, the side wall of the second layer may be formed to be inclined.

Aspects of some embodiments of the present invention include a display device including: a display panel in which a pixel including a pixel circuit and a light emitting element and a photo sensor including a sensor circuit and a light receiving element are located; and a readout circuit configured to sense the photo sensor, wherein the display panel includes: a base substrate; a thin film transistor layer that is located on the base substrate, in which a lower metal layer to which a low potential voltage is applied is located, that includes the pixel circuit, and that includes the sensor circuit connected to the lower metal layer; and an element layer that is located on the thin film transistor layer, that includes the light emitting element provided with a first pixel electrode electrically connected to the pixel circuit and a second pixel electrode to which the low potential voltage is applied, and that includes the light receiving element electrically connected to the sensor circuit and applied with the low potential voltage from the lower metal layer.

According to some embodiments, the element layer may include a partition wall surrounding the light receiving element without an opening.

According to some embodiments, the partition wall may include at least one of an acryl resin, an epoxy resin, a phenol resin, a polyamide resin, or a polyimide resin.

According to some embodiments, the readout circuit may receive different voltages according to an amount of light received by the photo sensor.

### BRIEF DESCRIPTION OF THE DRAWINGS

FIG. 1 illustrates a schematic system diagram of an electronic device according to some embodiments of the present disclosure.

FIG. 2 illustrates a display device and a processor according to some embodiments of the present disclosure.

FIG. 3 illustrates a system diagram of a display device according to some embodiments of the present disclosure.

FIG. 4 illustrates a sub-pixel and a photo sensor located in a first area of FIG. 3 according to some embodiments of the present disclosure.

FIG. 5 illustrates an equivalent circuit of a sub-pixel and a photo sensor according to some embodiments of the present disclosure.

FIG. 6 illustrates a front view of a display area according to some embodiments of the present disclosure.

FIG. 7 illustrates a cross-sectional view taken along the line A-A′ of FIG. 6 according to some embodiments of the present disclosure.

FIG. 8 illustrates an enlarged view of the area “X” of FIG. 7 according to some embodiments of the present disclosure.

FIG. 9 illustrates an another equivalent circuit of a sub-pixel and a photo sensor according to some embodiments of the present disclosure.

FIG. 10 illustrates another cross-sectional view taken along the line A-A′ of FIG. 7 according to some embodiments of the present disclosure.

FIG. 11A, FIG. 11B, and FIG. 11C illustrate shapes of partition walls according to some embodiments of the present disclosure.

### DETAILED DESCRIPTION

Aspects of some embodiments of the present disclosure will be described more fully hereinafter with reference to the accompanying drawings, in which embodiments of the disclosure are shown. As those skilled in the art would realize, the described embodiments may be modified in various different ways, all without departing from the spirit or scope of embodiments according to the present disclosure.

In order to more clearly describe aspects of some embodiments of the present disclosure, parts or portions that are irrelevant to the description are omitted, and identical or similar constituent elements throughout the specification are denoted by the same reference numerals. Therefore, the above-mentioned reference numerals may be used in other drawings.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc. may be exaggerated for clarity.

In addition, the expression “equal to or the same as” in the description may mean “substantially equal to or the same as”. That is, it may be the same enough to convince those skilled in the art to be the same. Even other expressions may be expressions from which “substantially” is omitted.

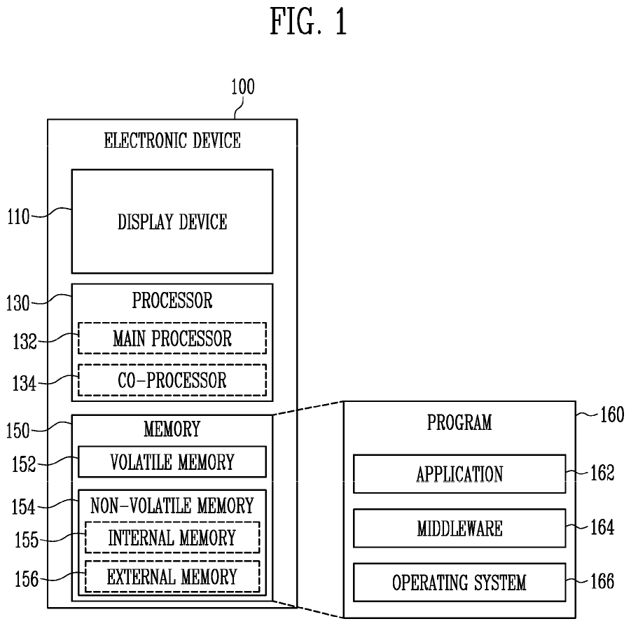

FIG. 1 illustrates a schematic system diagram of an electronic device 100 according to some embodiments of the present disclosure.

Referring to FIG. 1, the electronic device 100 according to some embodiments of the present disclosure may include a display device 110, a processor 130, and a memory 150.

The display device 110 may visually provide information to the outside (for example, a user) of the electronic device 100. For example, the display device 110 may include a display panel, a driving circuit, and the like. The display device 110 according to some embodiments of the present disclosure may include a touch sensor set to detect a touch and/or a pressure sensor set to measure an intensity of force generated by the touch.

The processor 130 may execute software (for example, program 160) to control at least one other constituent element (for example, a hardware or software constituent element) of the electronic device 100 connected to the processor 130, and may perform various data processing or calculations. The processor 130 may store data received from other constituent elements (for example, the display device 110) in a volatile memory 152 as at least some of data processing or calculation. The processor 130 may process instructions or data stored in the volatile memory 152. The processor 130 may store the processed result data in a non-volatile memory 154. The processor 130 may include a main processor 132 (for example, a central processing unit (CPU) or an application processor (AP)). The processor 130 may include an auxiliary processor 134 (for example, a graphic processing unit (GPU), a neural processing unit (NPU), an image signal processor, a sensor hub processor, a communication processor, or the like) that may operate independently or together with the main processor 132. For example, when the electronic device 100 includes the main processor 132 and the auxiliary processor 134, the auxiliary processor 134 may use less power than the main processor 132 or may be set to be specialized for a designated function. The auxiliary processor 134 may be implemented separately from the main processor 132 or as a portion of the main processor 132.

The auxiliary processor 134 may, for example, on behalf of the main processor 132 while the main processor 132 is in an inactive state (for example, a sleep state), or together with the main processor 132 while the main processor 132 is in an active state (for example, an application execution state), control at least some of functions or states related to at least one (for example, the display device 110) among the constituent elements of the electronic device 100. According to some embodiments of the present disclosure, the auxiliary processor 134 (for example, an image signal processor or a communication processor) may be implemented as some of other functionally related constituent elements (for example, a camera module, a communication module, and the like). According to some embodiments of the present disclosure, the auxiliary processor 134 (for example, a neural network processing device) may include a hardware structure specialized for processing an artificial intelligence model. The artificial intelligence model may be created through machine learning.

The memory 150 may store various data used by at least one constituent element (for example, the processor 130) of the electronic device 100. may include, for example, input data or output data for software (for example, the program 160) and instructions associated therewith. The memory 150 may include the volatile memory 152 or the non-volatile memory 154. The non-volatile memory 154 may include an embedded memory 155. The non-volatile memory 154 may further include an external memory 156.

The program 160 may be stored as software in the memory 150. For example, the program 160 may include an application 162, a middleware 164, an operating system 166, and the like.

The electronic device 100 according to some embodiments of the present disclosure may be referred to as a mobile station, mobile equipment (ME), user equipment (UE), a user terminal (UT), a subscriber station (SS), a wireless device, a handheld device, an access terminal (AT), or the like. The electronic device 100 according to some embodiments of the present disclosure may be, for example, a device having a communication function such as a mobile phone, a personal digital assistant (PDA), a smart phone, a wireless modem, and a laptop computer.

The electronic device 100 according to some embodiments of the present disclosure may include a power management module configured to manage power supplied to the electronic device 100. The power management module may be implemented as at least a portion of, for example, a power management integrated circuit (PMIC).

In the electronic device 100 according to some embodiments of the present disclosure, at least some of the constituent elements may be connected to each other through a communication method (for example, a bus, a general purpose input and output (GPIO), a serial peripheral interface (SPI), or a mobile industry processor interface (MIPI)) between peripheral devices and may exchange signals (for example, instructions or data) with each other.

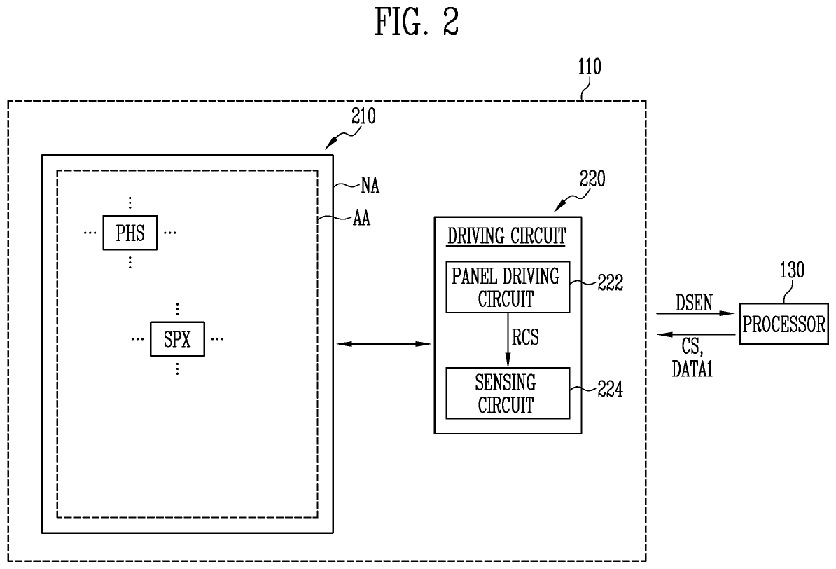

FIG. 2 illustrates the display device 110 and the processor 130 according to some embodiments of the present disclosure.

Referring to FIG. 2, the display device 110 according to some embodiments may include a display panel 210 and a driving circuit 220.

The display panel 210 may include a display area AA in which sub-pixels SPX are located, and a non-display area NA located in a peripheral area (for example, an edge area) of the display area AA. One or more sub-pixels SPX may be located in the display area AA. One or more photo sensors PHS may be located in the display area AA.

The sub-pixel SPX may be configured to display an image on the display device 110. The sub-pixel SPX may emit light with brightness corresponding to a voltage (for example, a data signal) inputted from the driving circuit 220.

The photo sensor PHS may be configured to detect an amount of received light. The photo sensor PHS may include a light receiving element. Depending on an intensity of light incident on the photo sensor PHS, an amount of a current flowing through the photo sensor PHS (or flowing through the light receiving element) may vary. The light incident to the photo sensor PHS may include reflected light. Here, the reflected light may include light that is emitted from the display device 110 to be reflected from an external object (for example, a surface of a person's finger). For example, the intensity of the current flowing through the photo sensor PHS may vary according to the intensity of the reflected light (or the amount of reflected light).

One or more pins (for example, pads) may be located in the non-display area NA. At least some components of the display panel 210 and the driving circuit 220 may be electrically connected through the pins.

The driving circuit 220 may include a panel driving circuit 222 and a sensing circuit 224.

The panel driving circuit 222 may generate a signal supplying a voltage to the display panel 210. For example, the driving circuit 220 may include a data driving circuit configured to output a data voltage, a scan driving circuit configured to supply a scan signal, an emission driving circuit configured to supply an emission signal, and the like. The driving circuit 220 may include, for example, a timing controller configured to control operation timings of the data driving circuit, the scan driving circuit, and the emission driving circuit.

The sensing circuit 224 may be configured to sense the photo sensor PHS located in the display panel 210.

The panel driving circuit 222 may output a read-out circuit control signal RCS. The sensing circuit 224 may receive the read-out circuit control signal RCS. A timing (or a length of a period) at which the sensing circuit 224 senses (for example, reads out) the photo sensor PHS may be controlled by the read-out circuit control signal RCS.

The sensing circuit 224 may convert a value sensed by the photo sensor PHS into a corresponding digital value. As necessary, the sensing circuit 224 may include an analog-to-digital converter configured to convert an analog voltage value into a corresponding digital value DSEN. The sensing circuit 224 may output the converted digital value DSEN. The processor 130 may receive the digital value DSEN.

The processor 130 may output a control signal CS for controlling an operation timing of the driving circuit 220. The processor 130 may output first image data DATA1 to the driving circuit 220.

The driving circuit 220 may receive the control signal CS and the first image data DATA1 to display an image through the sub-pixel SPX. The driving circuit 220 may receive the control signal CS to detect an amount of received light through the photo sensor PHS.

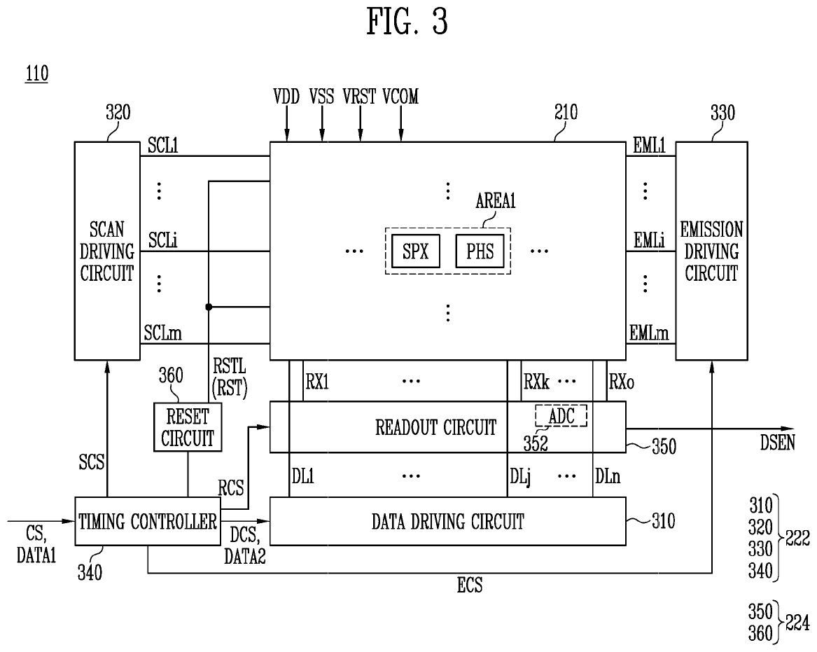

FIG. 3 illustrates a system diagram of the display device 110 according to some embodiments of the present disclosure.

Referring to FIG. 3, the display device 110 according to some embodiments of the present disclosure may include the display panel 210, a data driving circuit 310, a scan driving circuit 320, an emission driving circuit 330, a timing controller 340, a readout circuit 350, a reset circuit 360, and the like.

The aforementioned panel driving circuit 222 may include the data driving circuit 310, the scan driving circuit 320, the emission driving circuit 330, and the timing controller 340. The aforementioned sensing circuit 224 may include the readout circuit 350 and the reset circuit 360.

One or more sub-pixels SPX may be located in the display panel 210. One or more photo sensors PHS may be located on the display panel 210. One or more power voltages may be supplied to the display panel 210. The power voltage may refer to a voltage inputted to the sub-pixel SPX and/or the photo sensor PHS.

The power voltage may include, for example, a first power voltage VDD, a second power voltage VSS, a third power voltage VRST, and a fourth power voltage VCOM. The power voltage may be commonly inputted to a plurality of sub-pixels SPX and/or a plurality of photo sensors PHS. The power voltage is also referred to as a common voltage. The power voltage may be generated by, for example, a power management module.

A plurality of data lines DL1 to DLn (where n is an integer greater than or equal to 2) may be located in the display panel 210. The plurality of data lines DL1 to DLn may extend and be located in a first direction in the display panel 210. For example, the first direction may be a direction connecting upper and lower sides of the display panel 210 (for example, a column direction), or may be a direction connecting left and right sides of the display panel 210 (for example, a row direction). Hereinafter, for better understanding and ease of description, the first direction is described as being a direction connecting the upper and lower sides of the display panel 210 as an example, but the embodiments of the present disclosure are not limited thereto.

A plurality of scan lines SCL1 to SCLm (where m is an integer greater than or equal to 2) may be located in the display panel 210. The plurality of scan lines SCL1 to SCLm may extend and be located in a second direction in the display panel 210. The second direction may be, for example, a direction connecting the left and right sides of the display panel 210, or a direction connecting the upper and lower sides of the display panel 210. The second direction may be, for example, a direction that is perpendicular to the first direction. Hereinafter, for better understanding and ease of description, the second direction is described as being a direction connecting the left and right sides of the display panel 210 as an example, but the embodiments of the present disclosure are not limited thereto.

On the other hand, extending and forming (or arranging) in the first direction may mean extending and forming (or arranging) in a direction connecting the upper and lower sides as a whole, and partially extending in a direction different from the first direction is not excluded. For example, according to some embodiments of the present disclosure, at least one of the plurality of data lines DL1 to DLn may be designed to partially bypass and extend in a different direction from the first direction in order to avoid a specific area (for example, an area (e.g., a set or predetermined area) with high transmittance). The meaning of extending and forming (or arranging) in the second direction may also be understood as the same meaning as that of extending and forming (or arranging) in the first direction.

A plurality of emission lines EML1 to EMLm may be located in the display panel 210. The plurality of emission lines EML1 to EMLm may extend and be located in the second direction in the display panel 210.

A plurality of sensing lines RX1 to RXo (where o is an integer greater than or equal to 2) may be located in the display panel 210. The plurality of sensing lines RX1 to RXo may extend and be arranged in the first direction in the display panel 210.

One or more reset control lines RSTL may be located in the display panel 210.

The sub-pixel SPX may be electrically connected to one of the plurality of data lines DL1 to DLn. The sub-pixel SPX may be electrically connected to at least one of the plurality of scan lines SCL1 to SCLm. The sub-pixel SPX may be electrically connected to at least one of the plurality of emission control lines EML1 to EMLm.

The photo sensor PHS may be electrically connected to one of the plurality of sensing lines RX1 to RXo. According to some embodiments, the photo sensor PHS may be electrically connected to the reset control line RSTL. According to some embodiments, the photo sensor PHS may be electrically connected to at least one of the plurality of scan lines SCL1 to SCLm. According to some embodiments, the photo sensor PHS may be electrically connected to at least one of the plurality of emission control lines EML1 to EMLm.

The sub-pixel SPX and the photo sensor PHS may be electrically connected to one of the plurality of scan lines SCL1 to SCLm. The sub-pixel SPX and the photo sensor PHS may be electrically connected to one of the plurality of light emitting lines EML1 to EMLm.

According to some embodiments, the plurality of sub-pixels SPX may be arranged in a matrix configuration or arrangement in the display panel 210. In the matrix configuration, the plurality of sub-pixels SPX are arranged in an RGBG configuration or arrangement, or in a rhombus-shaped pentile (PENTILE™) structure.

The data driving circuit 310 may be configured to supply (apply or output) a data voltage to the plurality of data lines DL1 to DLn. The data driving circuit 310 may receive a data driving circuit control signal DCS and second image data DATA2, and may supply a data voltage corresponding to the image data to the plurality of data lines DL1 to DLn according to timing.

The scan driving circuit 320 may be configured to supply scan signals to the plurality of scan lines SCL1 to SCLm. According to some embodiments, the scan driving circuit 320 may sequentially supply scan signals to the plurality of scan lines SCL1 to SCLm. According to some embodiments, scan signals may be non-sequentially supplied to the plurality of scan lines SCL1 to SCLm. The scan driving circuit 320 may receive a scan driving circuit control signal SCS, and may supply scan signals to the plurality of scan lines SCL1 to SCLm according to timing.

The emission driving circuit 330 may be configured to supply emission signals to the plurality of emission lines EML1 to EMLm. According to some embodiments, the emission driving circuit 330 may sequentially supply emission signal to the plurality of emission lines EML1 to EMLm. According to some embodiments, the emission driving circuit 330 may non-sequentially supply emission signal to the plurality of emission lines EML1 to EMLm. The emission driving circuit 330 may receive an emission driving circuit control signal ECS, and may supply emission signals to the plurality of emission lines EML1 to EMLm according to timing.

The timing controller 340 may receive the control signal CS and the first image data DATA1 from the outside, and may generate and output the data driving circuit control signal DCS, the scan driving circuit control signal SCS, the emission driving circuit control signal ECS, the second image data DATA2, the read-out circuit control signal RCS, and the like, based on the received control signal CS and first image data DATA1.

The readout circuit 350 may be electrically connected to the plurality of sensing lines RX1 to RXo. The readout circuit 350 may sense the plurality of photo sensors PHS through the plurality of sensing lines RX1 to RXo. For example, the readout circuit 350 may integrate (also be referred to as a current sensing method) a current flowing through at least one of the plurality of sensing lines RX1 to RXo. For example, the readout circuit 350 may sense (also be referred to as a voltage sensing method) a voltage of at least one of the plurality of sensing lines RX1 to RXo. The readout circuit 350 may include a multiplexer configured to select one or more of the plurality of sensing lines RX1 to RXo and integrate current (or sense voltage) of the selected sensing line. The readout circuit 350 may include an analog-to-digital converter 352 configured to convert an analog voltage into the digital value DSEN.

The reset circuit 360 may supply a reset signal RST to the plurality of photo sensors PHS. When the reset signal RST is supplied to the photo sensor PHS, an electrical connection between the photo sensor PHS and a sensing line (for example, a k-th sensing line RXk) may be disconnected. A timing at which the reset circuit 360 outputs the reset signal RST may be controlled by a signal outputted from the timing controller 340.

One or more circuits configuring the panel driving circuit 222 may be located in the display device 110 as an integrated circuit (IC) type. For example, a source driver integrated circuit (SDIC) may include the data driving circuit 310.

One or more circuits configuring the panel driving circuit 222 may be formed together in a process of forming the display panel 210. For example, the scan driving circuit 320 may be formed together in a process of forming one or more circuit elements (for example, transistors and the like) included in the sub-pixel SPX and/or the photo sensor PHS.

The data driving circuit 310, the scan driving circuit 320, the emission driving circuit 330, and the timing controller 340 are only classified according to their functions within the panel driving circuit 222, and two or more constituent elements may be functionally separated within one integrated circuit. For example, the data driving circuit 310 and the timing controller 340 may be implemented as one integrated circuit and may be functionally separated within one integrated circuit. For example, the scan driving circuit 320 and the emission driving circuit 330 may be implemented as one integrated circuit and may be functionally separated within the integrated circuit.

The panel driving circuit 222 and the sensing circuit 224 are merely classified according to their functions within the display device. For example, the panel driving circuit 222 and the sensing circuit 224 may be mounted in one integrated circuit. For example, the panel driving circuit 222 and the sensing circuit 224 may be mounted on different integrated circuits.

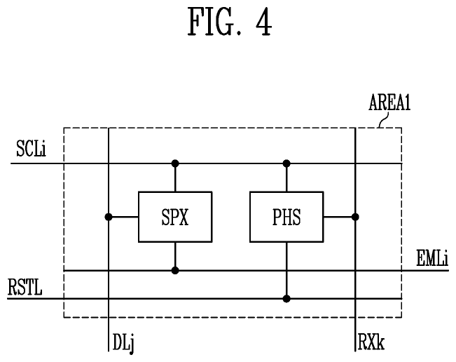

FIG. 4 illustrates the sub-pixel SPX and the photo sensor PHS located in a first area AREA 1 of FIG. 3.

The first area AREA 1 may include an area in which an i-th (i is an integer greater than or equal to 1 and less than or equal to m) scan line SCLi, an i-th emission line EMLi, a j-th (j is an integer greater than or equal to 1 and less than or equal to n) data line DLj, and a k-th (k is an integer greater than or equal to 1 and less than or equal to o) sensing line RXk are located. The first area AREA 1 may include an area in which the reset control line RSTL is located.

Referring to FIG. 4, the sub-pixel SPX located in the first area AREA 1 may be electrically connected to the i-th scan line SCLi, the i-th emission line EMLi, and the j-th data line DLj. The photo sensor PHS located in the first area AREA 1 may be electrically connected to the i-th scan line SCLi, the k-th sensing line RXk, and the reset control line RSTL.

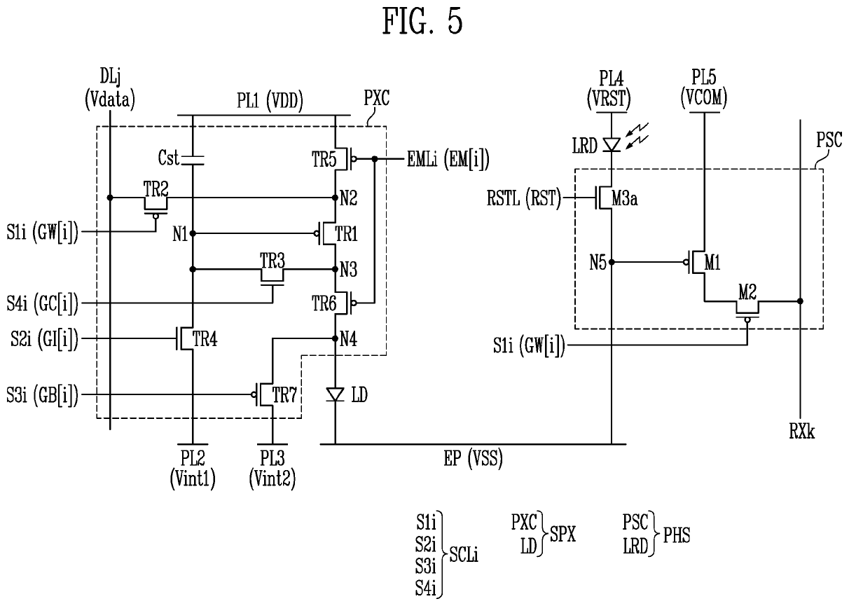

FIG. 5 illustrates an equivalent circuit of the sub-pixel SPX and the photo sensor PHS in the embodiments of the present disclosure.

Referring to FIG. 5, the sub-pixel SPX may include a pixel driving circuit PXC and a light emitting element LD. The photo sensor PHS may include a photo sensor driving circuit PSC and a light receiving element LRD.

The pixel driving circuit PXC may be configured to control a timing of a current flowing through the light emitting element LD and an amount of the current flowing through the light emitting element LD. The pixel driving circuit PXC may include two or more transistors and one or more capacitors. The pixel driving circuit PXC may be variously implemented by a person skilled in the art, but hereinafter, a structure in which the pixel driving circuit PXC includes seven transistors and one capacitor will be described as an example.

Referring to FIG. 5, the pixel driving circuit PXC may include first to seventh pixel transistors TR1 to TR7 and one capacitor Cst.

The first pixel transistor TR1 may be configured to switch an electrical connection between a second node N2 and a third node N3. The first pixel transistor TR1 may switch the electrical connection between the second node N2 and the third node N3 in response to a voltage of the first node N1. The first node N1 may be electrically connected to a gate electrode of the first pixel transistor TR1. The second node N2 may be electrically connected to one of a source electrode and a drain electrode of the first pixel transistor TR1. The third node N3 may be electrically connected to the other of the source electrode and the drain electrode of the first pixel transistor TR1. An amount of a current flowing through the first pixel transistor TR1 (or an amount of a current flowing through the light emitting element LD) may be controlled according to a value of a voltage applied to the first node N1. The first pixel transistor TR1 is also referred to as a driving transistor.

The second pixel transistor TR2 may be configured to switch an electrical connection between the second node N2 and the data line DLj. The second pixel transistor TR2 may transmit a data voltage Vdata applied to the data line DLj or a voltage corresponding thereto to the second node N2 in response to a first scan signal GW[i] of a turn-on level. The first scan signal GW[i] may be inputted to a first scan line S1i.

The third pixel transistor TR3 may be configured to switch an electrical connection between the first node N1 and the third node N3. The third pixel transistor TR3 may switch the electrical connection between the first node N1 and the third node N3 in response to a fourth scan signal GC[i]. The fourth scan signal GC[i] may be applied to a fourth scan line S4i. When the third pixel transistor TR3 is turned on, the first pixel transistor TR1 may operate like a diode.

The fourth pixel transistor TR4 may be configured to switch an electrical connection between the first node N1 and a second power line PL2. The fourth pixel transistor TR4 may switch the electrical connection between the first node N1 and the second power line PL2 in response to a second scan signal GI[i]. The second scan signal GI[i] may be applied to a second scan line S2i. A first initialization voltage Vint1 may be applied to the second power line PL2. When the fourth pixel transistor TR4 is turned on, the voltage of the first node N1 may be initialized to the first initialization voltage Vint1.

The fifth pixel transistor TR5 may be configured to switch an electrical connection between the second node N2 and a first power line PL1. The fifth pixel transistor TR5 may switch the electrical connection between the second node N2 and the first power line PL1 in response to an emission signal EM[i]. When the fifth pixel transistor TR5 is turned on, the first power voltage VDD may be applied to the second node N2.

The sixth pixel transistor TR6 may be configured to switch an electrical connection between the third node N3 and a fourth node N4. The sixth pixel transistor TR6 may switch the electrical connection between the third node N3 and the fourth node N4 in response to the emission signal EM[i]. The sixth pixel transistor TR6 and the fifth pixel transistor TR5 may be electrically connected to the same emission line EMLi. According to some embodiments, the sixth pixel transistor TR6 and the fifth pixel transistor TR5 may be connected to different emission lines.

The seventh pixel transistor TR7 may be configured to switch an electrical connection between the fourth node N4 and a third power line PL3. The seventh pixel transistor TR7 may switch the electrical connection between the fourth node N4 and the third power line PL3 in response to a third scan signal GB[i]. When the seventh pixel transistor TR7 is turned on, the voltage of the fourth node N4 may be initialized to a second initialization voltage Vint2.

The capacitor Cst may be configured to maintain the voltage of the first node N1. Accordingly, the voltage of the first node N1 may be maintained at the data voltage Vdata or a voltage corresponding thereto for one frame period. The capacitor Cst may include one electrode electrically connected to the first node N1 and the other electrode electrically connected to a power line (for example, the first power line PL1). For example, the data voltage Vdata is applied to one side electrode of the capacitor Cst, and the capacitor Cst may maintain the voltage of the first node N1 for one frame period. The capacitor Cst is also referred to as a storage capacitor.

The first to seventh pixel transistors TR1 to TR7 may each be an n-type transistor or a p-type transistor. The n-type transistor refers to a transistor in which an amount of current that is conducted when a voltage difference between a gate terminal and a source terminal increases in a positive direction increases. The p-type transistor refers to a transistor in which an amount of current that is conducted when a voltage difference between a gate terminal and a source terminal increases in a negative direction increases. In the n-type transistor, a turn-on level voltage is a high logic level voltage, and a turn-off level voltage is a low logic level voltage. In the p-type transistor, a turn-on level voltage is a low logic level voltage, and a turn-off level voltage is a high logic level voltage.

Referring to FIG. 5, among the seven transistors included in the pixel driving circuit PXC, the third pixel transistor TR3 and the fourth pixel transistor TR4 are the n-type transistors, and the remaining transistors TR1, TR2, TR5, TR6, and TR7 the p-type transistors. However, according to some embodiments, one or more of the third pixel transistor TR3 and the fourth pixel transistor TR4 may be implemented as a p-type transistor. According to some embodiments, one or more of the remaining transistors TR1, TR2, TR5, TR6, and TR7 may be implemented as an n-type transistor.

The transistor may have various kinds such as a thin film transistor (TFT), a field effect transistor (FET), and a bipolar junction transistor (BJT).

The transistors configuring the pixel driving circuit PXC may include an amorphous silicon (a-Si) semiconductor, an oxide semiconductor, a low temperature polycrystalline silicon (LTPS) semiconductor, and the like. For example, some of the seven transistors configuring the pixel driving circuit PXC may include a low temperature polycrystalline silicon semiconductor, and others thereof may include an oxide semiconductor.

For example, the third pixel transistor TR3 and the fourth pixel transistor TR4 may include an oxide semiconductor, and the remaining transistors TR1, TR2, TR5, TR6, and TR7 may include a low temperature polycrystalline silicon semiconductor. However, according to some embodiments, one or more of the third pixel transistor TR3 and the fourth pixel transistor TR4 may include an amorphous silicon semiconductor or a low temperature polycrystalline silicon semiconductor. According to some embodiments, one or more of the remaining transistors TR1, TR2, TR5, TR6, and TR7 may include an oxide semiconductor.

A first electrode (one of anode or cathode electrodes) of the light emitting element LD is electrically connected to the fourth node N4. A second electrode (the other of anode and cathode electrodes) of the light emitting element LD is electrically connected to a sixth power line EP. The light emitting element LD may generate light of a luminance (e.g., a set or predetermined luminance) in response to an amount of current (a driving current) supplied from the first transistor TR1. The second power voltage VSS is applied to the sixth power line EP. The second power voltage VSS has a relatively low voltage level. For example, the second power voltage VSS may have a positive voltage level, but may have a ground voltage level or a negative voltage level. The second power voltage VSS may be referred to as a low potential voltage.

The light emitting element LD may be selected as an organic light emitting diode. In addition, the light emitting element LD may be selected as an inorganic light emitting diode such as a micro light emitting diode (LED) or a quantum dot light emitting diode. Further, the light emitting element LD may be an element complexly made of organic and inorganic materials. In FIG. 5, the sub-pixel SPX is illustrated as including a single light emitting element LD, but according to some embodiments, the sub-pixel SPX may include a plurality of light emitting elements. The plurality of light emitting elements may be connected in series, in parallel, or in series/parallel to each other.

The photo sensor driving circuit PSC may include first to third sensor transistors M1, M2, and M3a.

The first sensor transistor M1 may be configured to switch an electrical connection between a fifth power line PL5 and the second sensor transistor M2. The first sensor transistor M1 may switch the electrical connection between the fifth power line PL5 and the second sensor transistor M2 according to a voltage level of a fifth node N5. A fourth power voltage VCOM may be applied to the fifth power line PL5.

The second sensor transistor M2 may be configured to switch an electrical connection between the first sensor transistor M1 and a sensing line RXk. The second sensor transistor M2 may electrically connect the first sensor transistor M1 and the sensing line RXk in response to a scan signal (for example, the first scan signal GW[i]).

The third sensor transistor M3a may be configured to switch an electrical connection between a fourth power line PL4 and the fifth node N5. The third sensor transistor M3a may switch the electrical connection between the fourth power line PL4 and the fifth node N5 in response to a reset signal RST. When the third sensor transistor M3a is turned on, a voltage of the fifth node N5 is initialized to the third power voltage VRST. The third power voltage VRST may be a turn-on level voltage (for example, a low logic level voltage) of the first sensor transistor M1.

The first to third sensor transistors M1, M2, and M3a may be implemented as p-type transistors or n-type transistors, respectively. Each of the first to third sensor transistors M1, M2, and M3a may include one of an amorphous silicon semiconductor, a low temperature polycrystalline silicon semiconductor, and an oxide semiconductor.

For example, a case in which the third sensor transistor M3a is implemented as an n-type transistor and the first and second sensor transistors M1 and M2 are implemented as p-type transistors will be described as an example, but the embodiments of the present disclosure are not limited thereto.

The light receiving element LRD may electrically connect the fifth node N5 and the sixth power line EP in response to light. The light receiving element LRD may be implemented as, for example, a photodiode. Referring to FIG. 5, the light receiving element LRD may be connected between the fourth power line PL4 and the third sensor transistor M3a.

On the other hand, referring to FIG. 5, both the light emitting element LD and the fifth node N5 are electrically connected to the sixth power line EP. For example, as shown in FIG. 4, when the sub-pixel SPX and the photo sensor PHS are adjacent to each other, a current (driving current) of the sub-pixel SPX may flow in the adjacent photo sensor PHS. Accordingly, sensing accuracy of the photo sensor PHS may be lowered.

In the embodiments of the present disclosure, the sub-pixel SPX and the photo sensor PHS may receive the second power voltage VSS from different electrodes. Accordingly, it is possible to prevent the driving current of the sub-pixel SPX from flowing in the adjacent photo sensor PHS.

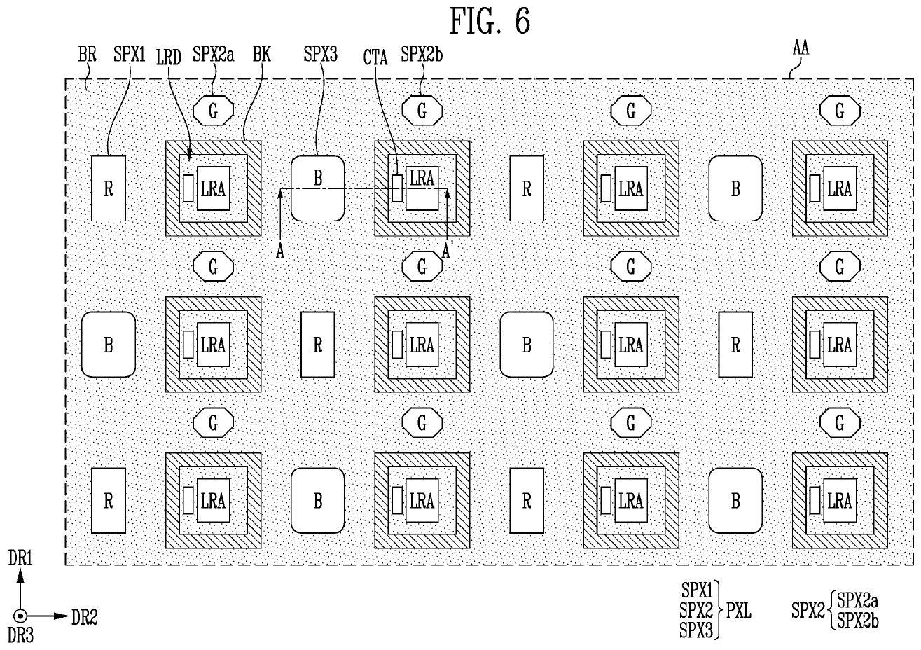

FIG. 6 illustrates a front view of the display area AA in the embodiments of the present disclosure.

Referring to FIG. 6, in the display area AA, sub-pixels SPX1, SPX2, and SPX3 and photo sensors PHS may be located. Hereinafter, light emitting areas R, G, and B of the sub-pixels SPX1, SPX2, and SPX3 and a light receiving region LRA of the photo sensor PHS will be mainly described.

The sub-pixels SPX1, SPX2, and SPX3 may be spaced apart from each other and located in the display area AA. For example, the first sub-pixel SPX1, the second sub-pixel SPX2, and the third sub-pixel SPX3 may each emit light with different wavelength bands (or different colors). For example, the first sub-pixel SPX1 may emit light in a first wavelength band (for example, a blue wavelength band). The second sub-pixel SPX2 may emit light in a second wavelength band (for example, a green wavelength band). The third sub-pixel SPX3 may emit light in a third wavelength band (for example, a red wavelength band). A pixel PXL may include the first sub-pixel SPX1, the second sub-pixel SPX2, and the third sub-pixel SPX3.

Meanwhile, the second sub-pixel SPX2 may be divided into a (2-1)-th sub-pixel SPX2a and a (2-2)-th sub-pixel SPX2b. For example, the (2-1)-th sub-pixel SPX2a and the (2-2)-th sub-pixel SPX2b may be alternately arranged along the first direction DR1 in the same pixel row (or the same horizontal line).

Referring to FIG. 6, the light receiving area LRA of the photo sensor PHS may be located between the first color light emitting area R of the first sub-pixel SPX1 and the third color light emitting area B of the third sub-pixel SPX3. The light receiving area LRA may correspond to an area in which a light receiving element OPD (see FIG. 5) is located.

An area of the light receiving area LRA may be smaller than an area of each of the light emitting areas R, G, and B. According to some embodiments, the area of the light receiving area LRA may be larger than that of at least one of the first color light emitting area R, the second color light emitting area G, or the third color light emitting area B.

Referring to FIG. 6, the area of the third color light emitting area B is shown to be larger than the area of the first color light emitting area R, and the area of the third color light emitting area B is shown to be larger than the area of the second color light emitting area G. However, the embodiments of the present disclosure are not limited thereto, and the area of the third color light emitting area B may be smaller than the area of the first color light emitting area R and/or the area of the second color light emitting area G.

A plurality of photo sensors PHS may detect light in wavelength bands of the same or similar bands. According to some embodiments, the plurality of photo sensors PHS may detect light in wavelength bands of different bands. For example, the plurality of photo sensors PHS may detect one of light in a red wavelength band, light in a green wavelength band, and light in a blue wavelength band.

Referring to FIG. 6, a bank area BR formed by a pixel defining film that partitions the light receiving area LRA and the light emitting areas R, G, and B, respectively, is shown. The bank area BR may include a light absorbing material. The bank region BR may absorb light introduced from the outside. For example, the bank area BR may be formed by applying a light absorbing agent.

The partition wall BK may be located on the bank area BR. The partition wall BK includes a partition wall member. The partition wall BK may be formed by extending the partition wall member in a third direction DR3 on a bank layer. The third direction DR3 may be a direction perpendicular to the first direction DR1 and the second direction DR2.

The partition wall BK may be located in a shape surrounding the photo sensor PHS on a plane (for example, on a plane along the first direction DR1 and the second direction DR2). For example, the partition wall BK may be located between the photo sensor PHS and the sub-pixels SPX1, SPX2, and SPX3.

The partition wall member included in the partition wall BK may have a reverse tapered shape. Even if constituent elements formed after the partition wall BK is formed in a manufacturing process are formed using a common mask, they may be separated from each other by a partition wall member BKM. A configuration formed after the partition wall BK is formed may include, for example, a second electrode layer of the light emitting element LD (see FIG. 5).

Referring to FIG. 6, the second electrode layers of the sub-pixels SPX1, SPX2, and SPX3 may be integrally formed. Accordingly, the second power voltage VSS (see FIG. 5) may be commonly applied to the sub-pixels SPX1, SPX2, and SPX3.

In a plan view, the photo sensor PHS is not connected to the second electrode layers of sub-pixels SPX1, SPX2, and SPX3 by the partition wall BK. The photo sensor PHS may receive the second power voltage VSS from a wire different from the second electrode layer. To this end, a contact area CTA may be provided in the partition wall BK. Accordingly, a problem in which a current flows from the sub-pixels SPX1, SPX2, and SPX3 toward the photo sensor PHS is alleviated (for example, eliminated).

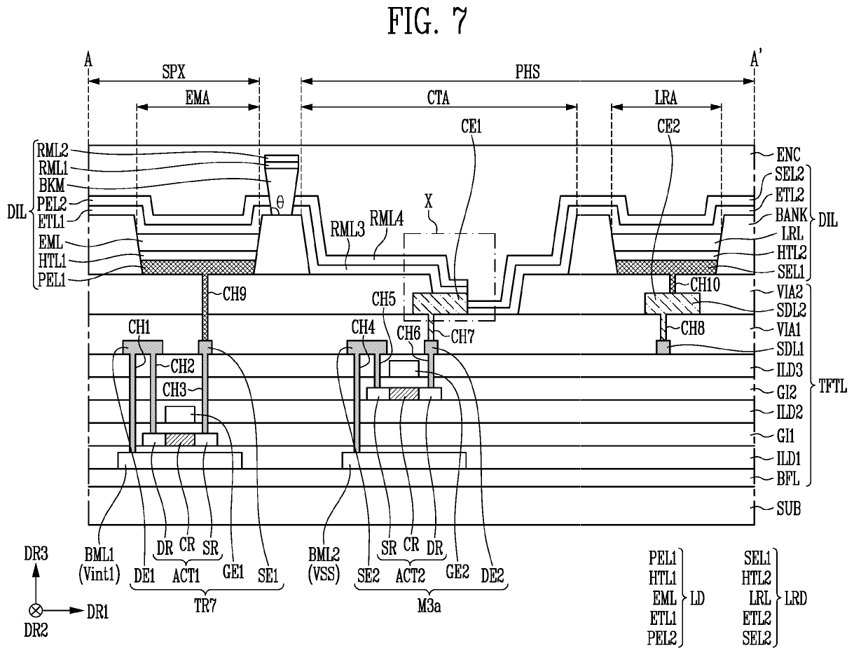

FIG. 7 illustrates a cross-sectional view taken along line A-A′ of FIG. 6.

Referring to FIG. 7 and FIG. 5 together, the pixel transistors TR1 to TR7 and the sensor transistors M1, M2, and M3a may be included in a thin film transistor layer TFTL.

FIG. 7 illustrates the seventh pixel transistor TR7 and the third sensor transistor M3a.

A base substrate SUB may include a base layer containing a polymer resin and a barrier layer of an inorganic insulating layer. For example, the base substrate SUB may include a first base layer, a first barrier layer, a second base layer, and a second barrier layer sequentially stacked. The first base layer and the second base layer may include a base layer and the second base layer 303 may include polyimide (PI), polyethersulfone (PES), polyarylate, polyetherimide (PEI), polyethyelenene napthalate (PEN), polyethyeleneterepthalate (PET), polyphenylene sulfide (PPS), polycarbonate (PC), cellulose triacetate (CTA), and/or cellulose acetate propionate (CAP). The first barrier layer and the second barrier layer may include an inorganic insulating material such as a silicon oxide, a silicon oxynitride, and/or a silicon nitride. The base substrate SUB may be flexible.

The thin film transistor layer TFTL including the pixel driving circuit PXC (see FIG. 5) and the photo sensor driving circuit PSC (see FIG. 5) may be provided on the base substrate SUB. The thin film transistor layer TFTL may include a semiconductor layer, a plurality of conductive layers, and a plurality of insulating layers.

A buffer layer BFL may be formed on the base substrate SUB. The buffer layer BFL may prevent impurities from spreading to the pixel transistors (for example, the first to seventh pixel transistors TR1 to TR7) and the sensor transistors (for example, the first to third sensor transistors M1, M2, and M3a). The buffer layer BFL may provide a flat surface on the base substrate SUB. The buffer layer BFL may include an inorganic insulating material such as a silicon oxide, a silicon oxynitride, or a silicon nitride. The buffer layer BFL may have a single-layer structure or a multi-layer structure including the above-mentioned material. The buffer layer BFL may be omitted depending on the material and process conditions of the base substrate SUB.

Lower metal layers BML1 and BML2 may be provided on the buffer layer BFL. A power voltage (for example, the first initialization voltage Vint1, the second power voltage VSS, or the like) may be supplied to the lower metal layers BML1 and BML2. Referring to FIG. 7, the first initialization voltage Vint1 may be applied to the first lower metal layer BML1. The second power voltage VSS may be applied to the second lower metal layer BML2. For example, the second lower metal layer BML2 may be grounded. The second lower metal layer BML2 may be electrically connected to the aforementioned sixth power line EP (see FIG. 5).

A first interlayer insulating layer ILD1 may be provided on the lower metal layers BML1 and BML2. The first interlayer insulating layer ILD1 may include an inorganic insulating layer including an inorganic material. For example, as the inorganic material, one or more of a polysiloxane, a silicon nitride, a silicon oxide, and a silicon oxynitride may be selected.

A first active pattern ACT1 may be provided on the first interlayer insulating layer ILD1. The first active pattern ACT1 may be formed of a silicon semiconductor. For example, the first active pattern ACT1 may be formed through a low temperature poly-silicon process (for example, a low temperature polycrystalline silicon (LTPS) process). At least a portion of the first active pattern ACT1 may be arranged to overlap the lower metal layer (for example, the first lower metal layer BML1) in a vertical direction.

A first gate insulating layer GI1 may be provided on the first active pattern ACT1. The first gate insulating layer GI1 may include an inorganic insulator such as a silicon oxide (SiO2), a silicon nitride (SiNx) (x is a positive number), a silicon oxynitride (SiON), an aluminum oxide (Al2O3), a titanium oxide (TiO2), a tantalum oxide (Ta2O5), a hafnium oxide (HfO2), and/or a zinc oxide (ZnO2).

A first gate electrode layer GE1 may be provided on the first gate insulating layer GI1. The first gate electrode layer GE1 may overlap a channel region CR of the first active pattern ACT1. The first gate electrode layer GE1 may include metal. For example, the first gate electrode layer GE1 may be made of at least one of metals such as gold (Au), silver (Ag), aluminum (Al), molybdenum (Mo), chromium (Cr), titanium (Ti), nickel (Ni), neodymium (Nd), or copper (Cu), or an alloy thereof. The first gate electrode layer GE1 may be formed as a single layer or as a multilayer in which two or more materials of metals and alloys are stacked.

A second interlayer insulating layer ILD2 may be provided on the first gate electrode layer GE1. The second interlayer insulating layer ILD2 may include an inorganic insulating layer including an inorganic material. For example, as the inorganic material, one or more of a polysiloxane, a silicon nitride, a silicon oxide, and a silicon oxynitride may be selected.

A second active pattern ACT2 may be provided on the second interlayer insulating layer ILD2. According to some embodiments, the second active pattern ACT2 may be formed of an oxide semiconductor. For example, the second active pattern ACT2 may be formed through a metal oxide semiconductor forming process. At least a portion of the second active pattern ACT2 may be arranged to overlap the lower metal layer (for example, the second lower metal layer BML2).

A second gate insulating layer GI2 may be provided on the second active pattern ACT2. The second gate insulating layer GI2 may be an inorganic insulating layer including an inorganic material. For example, as the inorganic material, one or more of a polysiloxane, a silicon nitride, a silicon oxide, and a silicon oxynitride may be selected.

A second gate electrode layer GE2 may be provided on the second gate insulating layer GI2. The second gate electrode layer GE2 may overlap a channel region CR of the second active pattern ACT2. The second gate electrode layer GE2 may include metal. For example, the second gate electrode layer GE2 may be made of at least one of metals such as gold (Au), silver (Ag), aluminum (Al), molybdenum (Mo), chromium (Cr), titanium (Ti), nickel (Ni), neodymium (Nd), or copper (Cu), or an alloy thereof. The second gate electrode layer GE2 may be formed as a single layer or as a multilayer in which two or more materials of metals and alloys are stacked.

A third interlayer insulating layer ILD3 may be provided on the second gate electrode layer GE2. For example, the third interlayer insulating layer ILD3 may be an inorganic insulating layer including an inorganic material. For example, as the inorganic material, one or more of a polysiloxane, a silicon nitride, a silicon oxide, and a silicon oxynitride may be selected.

A first source-drain electrode layer SDL1 may be provided on the third interlayer insulating layer ILD3. A first source electrode SE1, a first drain electrode DE1, a second source electrode SE2, and a second drain electrode DE2 may be implemented with the first source-drain electrode layer SDL1.

The first source electrode SE1 and the first drain electrode DE1 may be relatively determined. For example, according to some embodiments in which the first active pattern ACT1 is formed in a p-type (for example, embodiments formed through a low-temperature polycrystalline silicon process), an electrode to which a relatively low voltage is applied may function as a drain electrode, and an electrode to which a relatively high voltage is applied may function as a source electrode. Hereinafter, the first source electrode SE1 and the first drain electrode DE1 will be separately described based on the embodiments in which the first active pattern ACT1 is formed through a low temperature polycrystalline silicon process. However, the embodiments of the present disclosure are not limited thereto.

The second source electrode SE2 and the second drain electrode DE2 may be relatively determined. For example, in embodiments in which the second active pattern ACT2 is formed in an n-type (for example, embodiments formed through a metal oxide semiconductor process), an electrode to which a relatively low voltage is applied may function as a source electrode, and an electrode to which a relatively high voltage is applied may function as a drain electrode. Hereinafter, the second source electrode SE2 and the second drain electrode DE2 will be separately described based on the embodiments in which the second active pattern ACT2 is formed through a metal oxide semiconductor process. However, the embodiments of the present disclosure are not limited thereto.

The first drain electrode DE1 may be connected to the first lower metal layer BML1 through a first contact hole CH1. The first drain electrode DE1 may be connected to a drain region DR of the first active pattern ACT1 through a second contact hole CH2. The drain region DR of the first active pattern ACT1 is located on one side of the channel region CR.

The first source electrode SE1 may be connected to a source region SR of the first active pattern ACT1 through a third contact hole CH3. The source region SR of the first active pattern ACT1 is located on the other side of the channel region CR. However, according to the type of the first active pattern ACT1, the first drain electrode DE1 may function as a source electrode.

The second source electrode SE2 may be connected to the second lower metal layer BML2 through a fourth contact hole CH4. The second source electrode SE2 may be connected to the source region SR of the second active pattern ACT2 through a fifth contact hole CH5. The source region SR of the second active pattern ACT2 is located on one side of the channel region CR.

The second drain electrode DE2 may be connected to the drain region DR of the second active pattern ACT2 through a sixth contact hole CH6. The drain region DR of the second active pattern ACT2 is located on the other side of the channel region CR.

The aforementioned first source electrode SE1, first drain electrode DE1, first active pattern ACT1, and first gate electrode layer GE1 may configure the seventh pixel transistor TR7. The aforementioned second source electrode SE2, second drain electrode DE2, second active pattern ACT2, and second gate electrode layer GE2 may configure the third sensor transistor M3a.

The first source-drain electrode layer SDL1 may include an excellent conductive material. For example, the first source-drain electrode layer SDL1 may include a conductive material including molybdenum (Mo), aluminum (Al), copper (Cu), titanium (Ti), and the like. The first source-drain electrode layer SDL1 may be formed in a multi-layer structure or single-layer structure including the above materials. For example, the first source electrode SE1, the first drain electrode DE1, the second source electrode SE2, and the second drain electrode DE2 may have a multi-layer structure of Ti/Al/Ti.

A first planarization insulating layer VIA1 is located on the first source-drain electrode layer SDL1. The first planarization insulating layer VIA1 may include an organic insulating layer including an organic material. The first planarization insulating layer VIA1 may include a general purpose polymer such as polymethylmethacrylate or polystyrene, a polymer derivative having a phenolic group, an organic insulating material such as an acrylic polymer, an imide polymer, an aryl ether polymer, an amide polymer, a fluorine polymer, a p-xylene polymer, a vinyl alcohol polymer, and a blend thereof. The first planarization insulating layer VIA1 may perform a function of planarizing a region on the first source-drain electrode layer SDL1.

A second source-drain electrode layer SDL2 may be provided on the first planarization insulating layer VIA1. A first connection electrode CE1 and a second connection electrode CE2 may be implemented with the second source-drain electrode layer SDL2.

The first connection electrode CE1 may be connected to the first source-drain electrode layer SDL1 through a seventh contact hole CH7. For example, the first connection electrode CE may be connected to the drain electrode DE2 of the third sensor transistor M3a through the seventh contact hole CH7.

The second connection electrode CE2 may be connected to the first source-drain electrode layer SDL1 through an eighth contact hole CH8. For example, the second connection electrode CE2 may be connected to the first source-drain electrode layer SDL1 through the eighth contact hole CH8 to be applied with the third power voltage VRST.

The second source-drain electrode layer SDL2 may include an excellent conductive material. For example, the second source-drain electrode layer SDL2 may include a conductive material including molybdenum (Mo), aluminum (Al), copper (Cu), titanium (Ti), and the like. The second source-drain electrode layer SDL2 may be formed in a multi-layer structure or single-layer structure including the above materials. For example, the first connection electrode CE1 and the second connection electrode CE2 may have a multi-layer structure of Ti/Al/Ti.

A second planarization insulating film VIA2 may be located on the second source-drain electrode layer SDL2. The second planarization insulating layer VIA2 may include an organic insulating layer including an organic material. The second planarization insulating layer VIA2 may include a general purpose polymer such as polymethylmethacrylate or polystyrene, a polymer derivative having a phenolic group, an organic insulating material such as an acrylic polymer, an imide polymer, an aryl ether polymer, an amide polymer, a fluorine polymer, a p-xylene polymer, a vinyl alcohol polymer, and a blend thereof. The second planarization insulating layer VIA2 may perform a function of planarizing a region on the second source-drain electrode layer SDL2.

A device layer DIL including a first pixel electrode PEL1, a first sensor electrode SEL1, and a bank layer BANK may be provided on the second planarization insulating layer VIA2.

The device layer DIL includes the light emitting element LD connected to a pixel driving circuit (for example, the pixel driving circuit PXC of FIG. 5) and the light receiving element LRD connected to a sensor circuit (for example, the photo sensor driving circuit PSC of FIG. 5)

The light emitting element LD may include the first pixel electrode PEL1, a first hole transport layer HTL1, an emission layer EML, a first electron transport layer ETL1, and a second pixel electrode PEL2. The light receiving element LRD may include the first sensor electrode SEL1, a second hole transport layer HTL2, a light receiving layer LRL, a second electron transport layer ETL, and a second sensor electrode SEL2.

The first pixel electrode PEL1 and the first sensor electrode SEL1 may include a metal layer such as silver (Ag), magnesium (Mg), aluminum (Al), platinum (Pt), palladium (Pd), gold (Au), nickel (Ni), neodymium (Nd), iridium (Ir), chromium (Cr), and an alloy thereof, and/or an indium tin oxide (ITO), an indium zinc oxide (IZO), a zinc oxide (ZnO), and an indium tin zinc oxide (ITZO). The first pixel electrode PEL1 may be connected to the first source electrode SE1 through a ninth contact hole CH9. The first sensor electrode SEL1 may be connected to the second connection electrode CE2 through a tenth contact hole CH10. The first pixel electrode PEL1 and the first sensor electrode SEL1 may be formed in the same process through patterning using a mask.

The bank layer BANK (or a pixel defining film) partitioning the emission area EMA and the light receiving region LRA may be provided in at least a partial region on the second planarization insulating layer VIA2. The bank layer BANK may include an organic insulating layer including an organic material. As the organic material, one or more of an acryl resin, an epoxy resin, a phenolic resin, a polyamide resin, and a polyimide resin may be selected.

The bank layer BANK may include a light absorbing material. The bank layer BANK may serve to absorb light introduced from the outside by applying a light absorbing agent. For example, the bank layer BANK may include a carbon-based black pigment. However, it is not limited thereto, and the bank layer BANK may include an opaque metallic material such as chromium (Cr), molybdenum (Mo), an alloy of molybdenum and titanium (MoTi), tungsten (W), vanadium (V), niobium (Nb), tantalum (Ta), manganese (Mn), cobalt (Co), or nickel (Ni), which has a high light absorption rate.

The bank layer BANK may include openings corresponding to the emission area EMA, the light receiving area LRA, and the contact area CTA.

The first hole transport layer HTL1 may be provided on the first pixel electrode PEL1. The second hole transport layer HTL2 may be provided on the first sensor electrode SEL1. Through the first hole transport layer HTL1, holes may move to the emission layer EML, and through the second hole transport layer HTL2, holes may move to the light receiving layer LRL.

Depending on the materials of the emission layer EML and the light receiving layer LRL, the first hole transport layer HTL1 and the second hole transport layer HTL2 may be the same or different.

The emission layer EML may be provided on the first hole transport layer HTL1. The emission layer EML may include an organic emission layer. Depending on the organic material included in the emission layer EML, the emission layer EML may emit light in the first wavelength band (for example, the red wavelength band), in the second wavelength band (for example, the green wavelength band), or in the third wavelength band (for example, the blue wavelength band).

The light receiving layer LRL may be located on the second hole transport layer HTL2. The light receiving layer LRL may emit electrons in response to light of a specific wavelength band. Accordingly, an intensity of light (or an amount of light) may be sensed. An electron blocking layer may be further provided between the second hole transport layer HTL2 and the light receiving layer LRL. The electron blocking layer may prevent electrons of the light receiving layer LRL from moving to the second hole transport layer HTL2. The electron blocking layer may be omitted.

The light receiving layer LRL may include a low molecular weight organic material. For example, the light receiving layer LRL may be made of a phthalocyanines compound containing one or more of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn).

The low molecular weight organic material included in the light-receiving layer LRL may include a phthalocyanines compound containing one or more of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn).

The light receiving layer LRL may be configured of a bi-layer. The light receiving layer LRL may include a layer containing a phthalocyanines compound and a layer containing C60. The light receiving layer LRL may include one mixing layer in which a phthalocyanines compound and C60 are mixed. However, this is an example, and the light receiving layer LRL may include a polymer organic layer.

A light detection band of the light receiving element LRD may be determined according to the selection of the metal component of the phthalocyanines compound included in the light receiving layer LRL. For example, in the case of the phthalocyanines compound containing copper, it may absorb visible light in the band of about 600 to 800 nm (nanometers). In the case of the phthalocyanines compound containing tin (Sn), it may absorb light in the near-infrared wavelength band of about 800 to 1000 nm. Depending on the selection of the metal included in the phthalocyanines compound, the light receiving element LRD capable of detecting a wavelength of a user's desired band may be implemented. For example, the light receiving layer LRL may be formed to selectively absorb light in a red wavelength band, light in a green wavelength band, or light in a blue wavelength band.

An area of the light receiving area LRA may be smaller than that of the emission area EMA. According to some embodiments, the area of the light receiving area LRA may be larger than that of the emission area EMA.

The partition wall member BKM is provided in at least a portion of the bank layer BANK. The partition wall member BKM is formed to extend in the third direction DR3 on the bank layer BANK. The partition wall member BKM may include an organic insulating layer containing an organic material. As the organic material, one or more of an acryl resin, an epoxy resin, a phenolic resin, a polyamide resin, and a polyimide resin may be selected. The partition wall member BKM may include an inclined side surface. A width of the partition wall member BKM may gradually increase toward the third direction DR3. An angle θ between an inner side surface of the partition wall member BKM and an upper surface of the bank layer BANK may be greater than 90°.

The first electron transport layer ETL1 may be provided on the emission layer EML. The second electron transport layer ETL2 may be provided on the light receiving layer LRL. The first electron transport layer ETL1 and the second electron transport layer ETL2 are disconnected (or broken) by the partition wall member BKM. A first residual layer RML1 on the partition wall member BKM may be formed in the same process as the first electron transport layer ETL1 and the second electron transport layer ETL2.

The second pixel electrode PEL2 may be provided on the first electron transport layer ETL1. The second sensor electrode SEL2 may be provided on the second electron transport layer ETL2. The second pixel electrode PEL2 and the second sensor electrode SEL2 are disconnected (or broken) by the partition wall member BKM. A second residual layer RML2 on the partition wall member BKM may be formed in the same process as the second pixel electrode PEL2 and the second sensor electrode SEL2. For example, the second pixel electrode PEL2 may be grounded. The second pixel electrode PEL2 may be electrically connected to the aforementioned sixth power line EP (see FIG. 5).

The second pixel electrode PEL2, the second residual layer RML2, and the second sensor electrode SEL2 may include a metal layer made of silver (Ag), magnesium (Mg), aluminum (Al), platinum (Pt), palladium (Pd), gold (Au), nickel (Ni), neodymium (Nd), iridium (Ir), or chromium (Cr) and/or a light-transmitting conductive layer made of ITO, IZO, ZnO, or ITZO. For example, the second pixel electrode PEL2, the second residual layer RML2, and the second sensor electrode SEL2 may be formed of of multiple layers or more than a double layer including a thin metal layer. For example, the second pixel electrode PEL2, the second residual layer RML2, and the second sensor electrode SEL2 may include a triple layer of ITO/Ag/ITO.

Referring to FIG. 7, the bank layer BANK is removed from the contact area CTA. The second planarization insulating layer VIA2 may be removed from at least a portion of the contact area CTA. In the contact area CTA, the second source-drain electrode layer SDL2 may be exposed. The second sensor electrode SEL2 is connected to a side surface of the second source-drain electrode layer SDL2. Through this, the second sensor electrode SEL2 may function as a wire electrically connecting the third sensor transistor M3a and the light receiving element LRD.

The second power voltage VSS (see FIG. 5) is applied to the second pixel electrode PEL2. The second power voltage VSS (see FIG. 5) is applied to the second sensor electrode SEL2. However, the second pixel electrode PEL2 and the second sensor electrode SEL2 are physically disconnected. Accordingly, a path of current flowing from the sub-pixel SPX to the photo sensor PHS adjacent thereto is blocked. Accordingly, sensing accuracy of the photo sensor PHS may be increased.

An encapsulation layer ENC may be provided on the second pixel electrode PEL2, the second residual layer RML2, and the second sensor electrode SEL2. The encapsulation layer ENC may be provided as a single layer, and it may be provided as a multi-layer. According to some embodiments, the encapsulation layer ENC may have a stacked structure in which an inorganic material, an organic material, and an inorganic material are sequentially deposited. An uppermost layer of the encapsulation layer ENC may be formed of an inorganic material.

According to some embodiments, a touch screen panel may be provided on the encapsulation layer ENC. The touch screen panel may include a touch electrode configured to detect a user's touch. The touch screen panel may be implemented in a self-capacitance method or a mutual capacitance method. The touch screen panel may be provided in an in-cell type or an on-cell type.

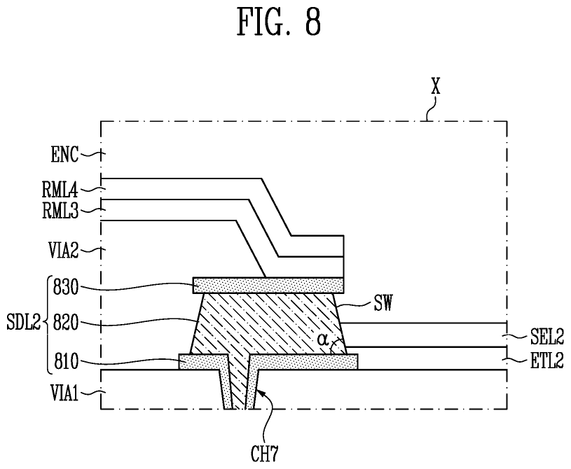

FIG. 8 illustrates an enlarged view of area “X” of FIG. 7.

Referring to FIG. 8, the second source-drain electrode layer SDL2 may include a first layer 810, a second layer 820, and a third layer 830. The second sensor electrode SEL2 is connected to the second layer 820 of the second source-drain electrode layer SDL2.

The second layer 820 may be thicker than the first layer 810 and the third layer 830. The second layer 820 may have less resistance than the first layer 810 and the third layer 830. The first layer 810 and the third layer 830 may function as a barrier to protect a contact area of a material configuring the second layer 820 with silicon (Si) to be reduced (for example, to be minimized). For example, the first layer 810 and the third layer 830 may include titanium (Ti). The second layer 820 may include aluminum (Al). For example, the second source-drain electrode layer SDL2 may have a triple layer Ti/Al/Ti structure.

The second layer 820 may be located inside the first layer 810. The second layer 820 may be located inside the third layer 830. For example, an area of an upper surface of the first layer 810 may be larger than an area of a lower surface of the second layer 820. For example, an area of a lower surface of the third layer 830 may be larger than an area of an upper surface of the second layer 820.

The second layer 820 may include an inclined side wall SW. For example, an angle α between the inside of the side wall SW of the second layer 820 and the first layer 810 may be smaller than 90°. As the angle α between the inside of the side wall SW of the second layer 820 and the first layer 810 is formed to be an acute angle, it may be easier for the second sensor electrode SEL2 to be connected to the side surface of the second layer 820. The second sensor electrode SEL2 is connected to the second layer 820 to be applied with the second power voltage VSS (see FIG. 7).

Referring to FIG. 8, a third residual layer RML3 and a fourth residual layer RML4 are located on the second source-drain electrode layer SDL2. The third residual layer RML3 may be formed in the same process as the second electron transport layer ETL2. The third residual layer RML3 and the second electron transport layer ETL2 may be disconnected from each other due to a step caused by the second source-drain electrode layer SDL2. The fourth residual layer RML4 may be formed in the same process as the second sensor electrode layer SEL2. The fourth residual layer RML4 and the second sensor electrode layer SEL2 may be disconnected from each other due to the step caused by the second source-drain electrode layer SDL2.

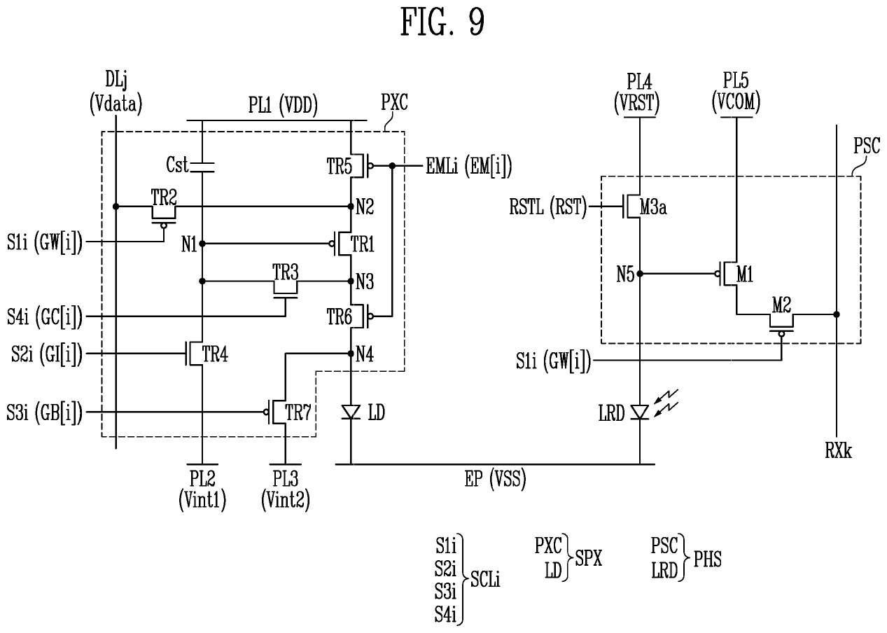

FIG. 9 illustrates another equivalent circuit of the sub-pixel SPX and the photo sensor PHS in the embodiments of the present disclosure.

Compared with FIG. 5, there is a difference only in that the light receiving element LRD is located between the photo sensor driving circuit PSC and the sixth power line EP. A description of the remaining components is as described in FIG. 5.

As described in FIG. 5, when the current (driving current) flowing through the sub-pixel SPX flows in the direction of the photo sensor PHS, the sensing accuracy of the photo sensor PHS is lowered. Therefore, a structure in which the sub-pixel SPX and the photo sensor PHS receive the second power voltage (VSS) through different electrodes is proposed.

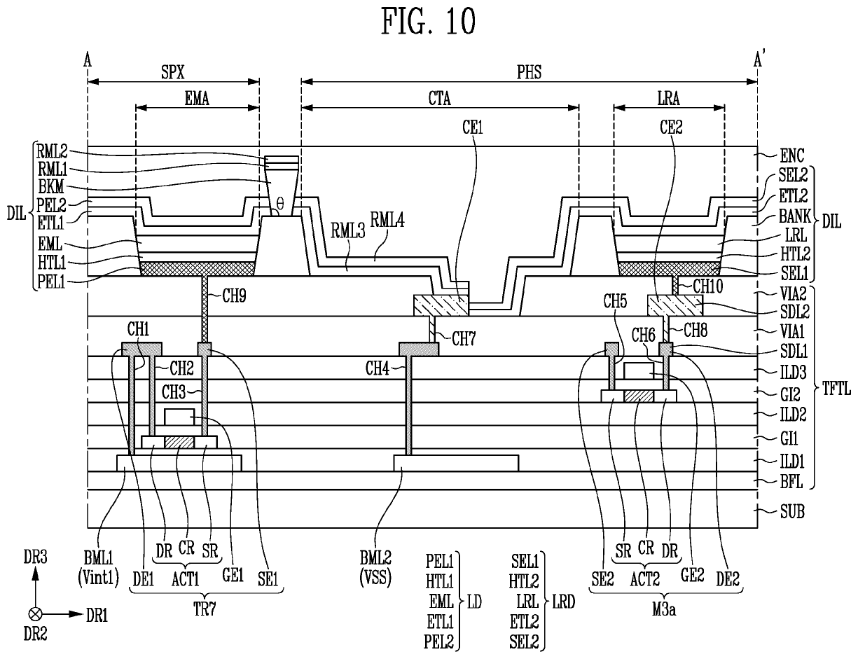

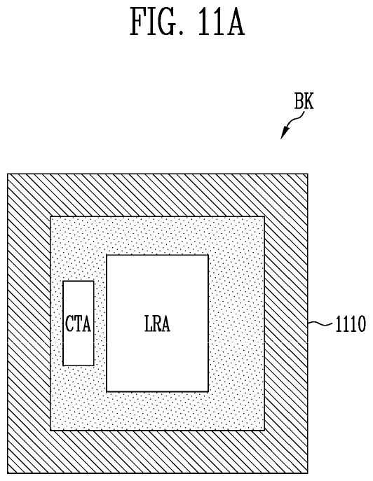

FIG. 10 illustrates another cross-sectional view taken along line A-A′ of FIG. 7.

Compared with the cross-sectional view of FIG. 7, there is a difference only in that the light receiving element LRD is connected between the second lower metal layer BML2 and the third sensor transistor M3a.

Referring to FIG. 10, the second sensor electrode SEL2 is connected to the first source-drain electrode layer SDL1. The first source-drain electrode layer SDL1 to which the second sensor electrode SEL2 is connected is connected to the second lower metal layer BML2. The second sensor electrode SEL2 may be electrically connected to the second lower metal layer BML2. The first sensor electrode SEL1 is electrically connected to the third sensor transistor M3a through the second connection electrode CE2.

A fourth power voltage VRST (see FIG. 9) may be applied to source electrode SE2 of the third sensor transistor M3a. A description of the remaining components will be replaced with the description of FIG. 7.

Through this, the second pixel electrode PEL2 and the second sensor electrode SEL2 are separated, and the problem of current flowing from the sub-pixel SPX toward the photo sensor PHS is alleviated (for example, eliminated). Accordingly, the sensing accuracy of the photo sensor PHS may be increased.

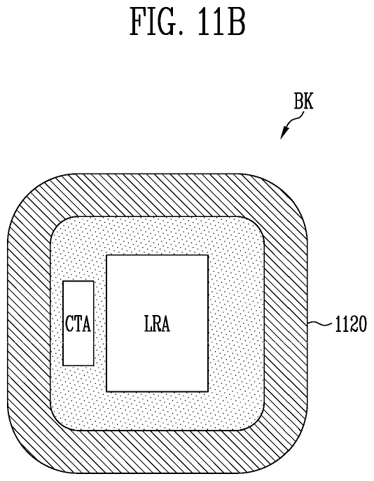

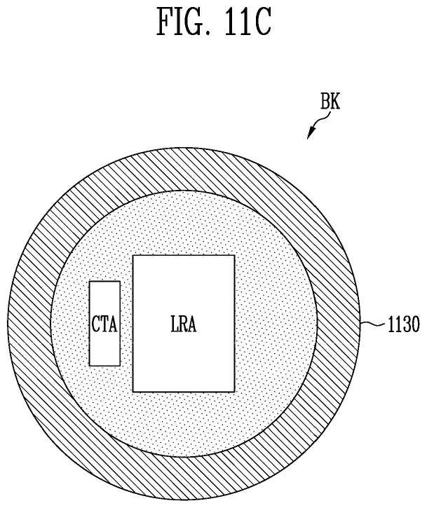

FIG. 11A, FIG. 11B, and FIG. 11C illustrate shapes of partition walls BK in the embodiments of the present disclosure as examples.

Referring to FIG. 11A to FIG. 11C, the shape of the partition wall BK may be variously designed. For example, referring to FIG. 11A, the partition wall BK may be formed in an angled quadrangular shape 1110 in a plan view. For example, referring to FIG. 11B, the partition wall BK may be formed in a quadrangular shape 1120 having curved surfaces at vertices. For example, referring to FIG. 11C, the partition wall BK may be formed in a circular shape 1130. The embodiments of the present disclosure are not limited thereto, and the partition wall BK may be formed to have a triangular shape or a polygonal shape having five or more vertices.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

In a display panel, a display device including the same, and a manufacturing method thereof according to some embodiments of the present disclosure, it may be possible to improve sensing accuracy of a photo sensor.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims. Therefore, those skilled in the art will understand that various modifications and other equivalent embodiments of the present disclosure are possible. Consequently, the true technical protective scope of the present disclosure must be determined based on the technical spirit of the appended claims, and their equivalents.

What is claimed is:

1. A display panel comprising:
a base substrate;
a thin film transistor layer on the base substrate and comprising:
a lower metal layer configured to receive a low potential voltage;
a pixel circuit including at least one transistor; and
a sensor circuit electrically connected to the lower metal layer; and
an element layer on the thin film transistor layer having a light emitting element comprising:
a first pixel electrode electrically connected to the pixel circuit;
a second pixel electrode configured to receive the low potential voltage; and
a light receiving element electrically connected to the sensor circuit and configured to receive the low potential voltage from the lower metal layer.

2. The display panel of claim 1, wherein the element layer further includes a partition wall member surrounding the light receiving element.

3. The display panel of claim 1, wherein the thin film transistor layer includes:
a multi-layered source-drain electrode layer; and
a planarization insulating film exposing at least a portion of the source-drain electrode layer, wherein
the lower metal film is electrically connected to the source-drain electrode layer.

4. The display panel of claim 3, wherein the second pixel electrode includes a conductive layer having light transmission, and
the light emitting element includes:
a first sensor electrode connected to the source-drain electrode layer; and
a second sensor electrode includes the conductive layer; and
the second sensor electrode is connected to a side surface of the exposed source-drain electrode layer.

5. The display panel of claim 4, wherein
the source-drain electrode layer includes first and third layers containing titanium and a second layer containing aluminum, and
the second sensor electrode is connected to the second layer of the source-drain electrode layer.

6. The display panel of claim 5, wherein
the second layer includes an inclined side wall, and
the second sensor electrode is connected to the inclined side wall of the second layer.

7. The display panel of claim 4, wherein the second pixel electrode and the second sensor electrode are disconnected from each other.

8. The display panel of claim 1, wherein the thin film transistor layer includes:
a buffer layer on the base substrate;
the lower metal layer on the buffer layer;
a first interlayer insulating layer covering the lower metal layer;
a first active pattern on the first interlayer insulating layer;
a first gate insulating layer covering the first active pattern and overlapping a channel region of the first active pattern;
a first gate electrode layer on the first gate insulating layer;
a second interlayer insulating layer covering the first gate electrode layer;
a second active pattern on the second interlayer insulating layer;
a second gate insulating layer covering the second active pattern;
a second gate electrode layer on the second gate insulating layer and overlapping a channel region of the second active pattern;
a third interlayer insulating layer covering the second gate electrode layer; and
a first source-drain electrode layer on the third interlayer insulating layer and connected to the lower metal layer, the first active pattern, and the second active pattern.

9. The display panel of claim 8, wherein
the first source-drain electrode layer includes:
a first source electrode connected to a source region of the first active pattern;
a first drain electrode connected to a drain area of the first active pattern;
a second source electrode connected to the lower metal layer and a source region of the second active pattern; and
a second drain electrode connected to a drain area of the second active pattern.

10. The display panel of claim 8, wherein
the thin film transistor layer further includes:
a first planarization insulating layer covering the first source-drain electrode layer;
a second source-drain electrode layer on the first planarization insulating film and connected to the first source-drain electrode layer; and
a second planarization insulating layer on the second source-drain electrode layer and exposing at least a portion of the second source-drain electrode layer.

11. The display panel of claim 10, wherein
the second source-drain electrode layer and the light receiving element are connected in an area in which at least a portion of the second planarization insulating layer is removed so that at least a portion of the second source-drain electrode layer is exposed.

12. A manufacturing method of a display panel, the method comprising:
forming a lower metal layer on a base substrate;
forming a first active pattern on the lower metal layer;
forming a first gate electrode layer overlapping a channel region of the first active pattern;
forming a second active pattern on the first gate electrode layer;
forming a second gate electrode layer overlapping a channel region of the second active pattern;
forming a first source-drain electrode layer that includes a first source electrode connected to a source region of the first active pattern, a first drain electrode connected to a drain region of the first active pattern, a second source electrode connected to a source region of the second active pattern and the lower metal layer, and a second drain electrode connected to a drain region of the second active pattern;
forming a second source-drain electrode layer including a connection electrode connected to the second drain electrode;
forming a first pixel electrode of a light emitting element and a first sensor electrode of a light receiving element;
forming an emission layer on the first pixel electrode;
forming a light receiving layer on the first sensor electrode; and
forming a light transmitting conductive layer that includes a second pixel electrode formed on the emission layer and a second sensor electrode of a light receiving element connected to the second source-drain electrode layer.

13. The manufacturing method of the display panel of claim 12, further comprising:
forming the first active pattern using a low temperature polycrystalline silicon process; and
forming the second active pattern using a metal oxide semiconductor process.

14. The manufacturing method of the display panel of claim 12, further comprising
forming a first planarization insulating layer covering the first source-drain electrode layer;
forming a second source-drain electrode layer connected to the first source-drain electrode layer on the first planarization insulating layer;
forming a second planarization insulating layer on the second source-drain electrode layer;
forming a bank layer on the second planarization insulating layer;
forming a partition wall member on the bank layer; and
removing at least a portion of the second planarization insulating layer and at least a portion of the bank layer and exposing the second source-drain electrode layer.

15. The manufacturing method of the display panel of claim 12, wherein forming the second source-drain electrode layer further comprises:
forming a first layer containing titanium;
forming a second layer containing aluminum and having a narrower width than the first layer; and
forming a third layer containing titanium and having a wider width than the second layer, and
wherein forming the light transmitting conductive layer further comprises:
connecting a second sensor electrode of the light receiving element and a side wall of the second layer.

16. The manufacturing method of the display panel of claim 15, the side wall of the second layer is formed to be inclined.

17. A display device comprising:
a display panel comprising:
a pixel including a pixel circuit and a light emitting element; and
a photo sensor including a sensor circuit and a light receiving element; and
a readout circuit configured to sense the photo sensor,
wherein the display panel comprises:
a base substrate;
a thin film transistor layer on the base substrate and comprising:
a lower metal layer configured to receive a low potential voltage;
the pixel circuit, and
the sensor circuit connected to the lower metal layer; and
an element layer on the thin film transistor layer comprising:
the light emitting element having a first pixel electrode electrically connected to the pixel circuit and a second pixel electrode configured to receive the low potential voltage; and
the light receiving element electrically connected to the sensor circuit and configured to receive the low potential voltage from the lower metal layer.

18. The display device of claim 17, wherein the element layer includes a partition wall surrounding the light receiving element without an opening.

19. The display device of claim 18, wherein the partition wall includes at least one of an acryl resin, an epoxy resin, a phenol resin, a polyamide resin, or a polyimide resin.

20. The display device of claim 17, wherein the readout circuit is configured to receive different voltages according to an amount of light received by the photo sensor.
